(19) United States
(12) Patent Application Publication
(10) Pub. No.: US 2014/0021851 A1
(43) Pub. Date: Jan. 23, 2014

(54) SUBSTRATE FOR LED MODULE AND METHOD FOR MANUFACTURING THE SAME

(71) Applicant: SAMSUNG ELECTRO-MECHANICS CO., LTD., Suwon (KR)

(72) Inventor: Cheol Ho HEO, Suwon (KR)

(73) Assignee: SAMSUNG ELECTRO-MECHANICS CO., LTD., Suwon (KR)

(21) Appl. No.: 13/944,496

(22) Filed: Jul. 17, 2013

(30) Foreign Application Priority Data
Jul. 19, 2012 (KR) 10-2012-0078806

(51) Int. Cl. H05K 1/03; H05K 3/10; H05B 33/02

(52) U.S. Cl. CPC H05K 1/0306; H05B 33/02; H05K 3/108
USPC 313/113; 174/250; 174/255; 427/97.3; 427/596; 427/97.4; 205/122

(57) ABSTRACT

As a substrate for an LED module and a method for manufacturing the same, they teach a substrate for an LED module and a method for manufacturing the same which including a base substrate, an insulating layer formed on a remaining region except a chip mounting region A in the base substrate, an electrode layer formed on the insulating layer, an oxide layer formed on the chip mounting region A of the base substrate and a high reflection layer formed on a top surface of the oxide layer.

### CROSS-REFERENCE TO RELATED APPLICATIONS

This application claims the benefit of Korean Patent Application No. 10-2012-0078806 filed with the Korea Intellectual Property Office on Jul. 19, 2012, the disclosure of which is incorporated herein by reference.

### BACKGROUND OF THE INVENTION

1. Field of the Invention

The present invention relates to a substrate for a LED module and a method for manufacturing the same; and, more particular, to a substrate for a LED module provided with a high reflection layer and a method for manufacturing the same.

2. Description of the Related Art

In recent, a light emitting diode (hereinafter referred to as LED) has been come into the spotlight as an illumination means or a light emitting means capable of realizing weight lightening, slimness and power saving. The LED device is as a light device to emit lights while applying currents to a pn junction of a semiconductor in a forward and is manufactured by using III-V group semiconductor crystals. Due to the development of an epitaxial growing technology and a light emitting device process technology of the semiconductor, the LED having excellent conversion efficiency has been developed and widely used for various fields.

Such LED module is manufactured as a module in a body, and it is general that the LED module is manufactured by mounting an LED package on a printed circuit board (PCB) for a conventional LED module through a surface mounted technology (SMT).

In case of the PCB for the LED module used in the LED module, since the shape or material thereof must be manufactured to meet the shape and material characteristics of the LED device, the material having excellent strength and small thermal strain is utilized. Particularly, since the PCB for the LED module has directionality, there are problems that an additional member such as a reflection plate or a light guide plate is utilized according to the device mounting shape of the PCB for the LED module during the manufacture thereof. That is, if the LED device is mounted on the PCB for the conventional LED module, a predetermined amount of lights are wasted due to the directionality of the LED light, thereby decreasing the efficiency.

According to this, in case of the PCB for the LED module used in the LED module, the aluminum material having excellent light reflectivity is used as the base substrate. And also, in order to realize more excellent light reflectivity, the surface of the base substrate is mirrored.

In the publication number 10-2010-0017841 (hereinafter referring to as a prior art reference 1) published in K.R. publication patent gazette, in order to increase the light reflectivity of the substrate for the LED module, there is proposed a metal base circuit substrate in characterized in that a white color layer is installed on an insulation layer.

However, reviewing the invention of the prior art reference 1, it contains a high-priced titanium dioxide as the white color dye of the white color layer and this white color layer is formed on the whole surface of the insulation layer, thereby increasing the manufacturing cost.

As a method for manufacturing an LED module substrate for increasing the light reflectivity, in the publication number 10-2010-0123155 (hereinafter referring to as a prior art reference 2) published in K.R. publication patent gazette, there is suggested that a method for manufacturing a printed circuit board for mounting an LED device includes a circuit pattern forming step of forming a circuit pattern on a base substrate; a photo-resist coating step of coating the photo-resist on the circuit pattern; a reflection layer forming step of forming a reflection layer made of a metal layer on a surface of the coated photo-resist; and an outward shape forming step of forming an outward shape of the printed circuit board by punching inside/outside of the circuit pattern.

However, since the manufacturing method of the prior art reference 2 is implemented through a stacking process due to the coating of the reflection layer as a light reflective member, the processes are complex related to the circuit pattern, thereby increasing the manufacturing cost.

### RELATED ART DOCUMENT

### Patent Document

(Patent Document 1) Korean Patent Laid-open publication No. 10-2010-0017841

(Patent Document 2) Korean Patent Laid-open Publication No. 10-2010-0123155

### SUMMARY OF THE INVENTION

The present invention has been invented in order to overcome the above-described problems and it is, therefore, an object of the present invention to provide a substrate for an LED module having excellent light reflectivity with simplifying fabrication processes and saving the manufacturing cost and a method for manufacturing the same.

In accordance with one aspect of the present invention to achieve the object, there is provided a substrate for an LED module including: a base substrate; an insulating layer formed on a remaining region except a chip mounting region A in the base substrate; an electrode layer formed on the insulating layer; an oxide layer formed on the chip mounting region A of the base substrate; and a high reflection layer formed on a top surface of the oxide layer.

And also, the oxide layer is made of oxide formed by oxidizing the base substrate.

And also, the oxide layer includes any one or two among alumina Al₂O₃, magnesium oxide MgO, manganese oxide MnO, zinc oxide ZnO, titanium TiO₂, hafnium oxide HfO₂, tantalum oxide Ta₂O₅ and niobium Nb₂O₃.

And also, the chip mounting region A of the base substrate is in a shape of circle or in a shape of rectangle.

And also, the high reflection layer is a metal thin film formed by a deposition process.

And also, the high reflection layer includes any one among aluminum Al, titanium Ti, silver Ag, nickel Ni and chrome Cr or an alloy thereof.

And also, the base substrate is made of any one among aluminum Al, magnesium Mg, manganese Mn, zinc Zn, hafnium Hf, tantalum Ta and niobium Nb or an alloy thereof.

And also, the substrate for an LED module further includes an LED chip mounted on the top surface of the reflection layer and connected to the electrode layer by a wire bonding.

And also, the substrate for an LED module further includes a plating layer formed on a surface of the electrode layer so as to be wire bonded to the LED chip.

In accordance with another aspect of the present invention to achieve the object, there is provided a method for manufacturing a substrate for an LED module including: (a) preparing a base substrate; (b) attaching a mask formed thereon an opening unit according to a predetermined pattern on a surface of the base substrate; (c) oxidizing the surface of the base substrate exposed through the opening unit; (d) forming an high reflection layer on an oxide layer formed by an oxidation process; (e) after removing the mask, forming an insulating layer on a remaining region except a chip mounting region A in the base substrate; and (f) forming an electrode layer on the insulating layer.

And also, the step (d) is performed by metal deposition processing the surface of the base substrate under the condition that the mask is attached.

And also, the metal deposition process utilizes any one among a sputtering, a plating, a thermal deposition, an e-beam deposition, a physical vapor deposition (PVD) and a chemical vapor deposition (CVD).

And also, the opening unit has a shape of circle or rectangle.

And also, a width of the opening unit is larger than that of the chip mounting region A in the base substrate.

And also, a difference between the width of the opening unit and the width of the chip mounting region A is ranging from 0.01 to 0.2 of the chip mounting region A.

And also, the oxidation treatment is an anodizing process or a plasma electrolytic oxidation process.

And also, the method for manufacturing a substrate for an LED module further includes, after the step (c), polishing a whole surface of the base substrate.

And also, the electrode layer is formed by any one among an additive process, a subtractive process or a semi-additive process.

And also, in the step (e), the insulting layer is formed so as to cover the oxide layer and the high refection layer exceeding to the chip mounting region A of the base substrate.

And also, the method for manufacturing a substrate for an LED module further includes, after the step (f), forming a plating layer on a surface of the electrode layer through an electroless plating such as an electoless nickel immersion gold (ENIG), an electroless nickel autocatalytic gold (ENAG), an electroless nickel electroless palladium immersion gold (ENEPIG) or the like.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing a substrate of an LED module in accordance with an embodiment of the present invention;

FIG. 2 is a plan view showing a substrate of an LED module in accordance with an embodiment of the present invention;

FIG. 3 is a cross-sectional view showing a substrate of an LED module in accordance with another embodiment of the present invention;

FIGS. 4 to 9 are process diagrams showing a method for manufacturing a substrate of an LED in accordance with another embodiment of the present invention: and

FIGS. 10 to 12 are process diagrams showing a method for manufacturing a substrate of an LED in accordance with another embodiment of the present invention.

### DETAILED DESCRIPTION OF THE PREFERABLE EMBODIMENTS

Embodiments of the present invention for achieving the above objects will be described with reference to the accompanying drawings. In the specification, like reference numerals denote like elements, and duplicate or redundant descriptions will be omitted for conciseness.

It should be noted that the singular forms ‘a’ ‘an’ and ‘the’ are intended to include the plural forms as well, unless the context clearly indicates otherwise. It should be understood that the terms ‘comprise’, ‘include’ and ‘have’, when used in this specification, specify the presence of stated features or elements, but do not preclude the presence or addition of one or more other features, elements, or combinations thereof.

The drawings referred to in the present specification will be described exaggeratedly in a shape, a size, a thickness or the like in order to effectively explain the technical features of the present invention as an example to represent the embodiments of the present in the present invention .

Hereinafter, the constructions and effects of the present invention will be described in more detail with reference to the accompanying drawings.

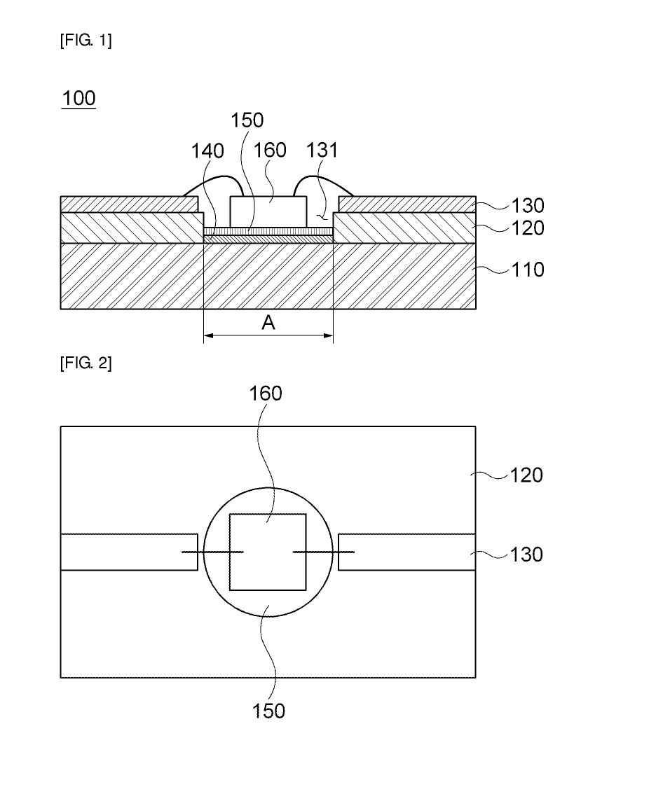

FIG. 1 is a cross-sectional view showing a substrate of an LED module in accordance with an embodiment of the present invention.

Referring to FIG. 1, the substrate 100 for the LED module in accordance with the present invention may includes a base substrate 110, an insulating layer 120, an electrode layer 130, an oxide layer 140 and a high reflection layer 150.

The base substrate 110 plays a role of discharging heat generated while the LED chip 160 is emitted to a bottom surface side of the base substrate 110. Accordingly, the base substrate 110 may be made of a metal material including any one among aluminum Al, magnesium Mg, manganese Mn, zinc Zn, titanium Ti, hafnium Hf, tantalum Ta and niobium Nb or an alloy thereof.

If the base substrate made of a metal material is used, it has an excellent thermal conductivity and the heat generated in the LED chip 160 is effectively discharged. However, in the present invention, it is not limited to such metal substrate, but a conventional epoxy resin or a polyimide based substrate can be also used as the base substrate according to the characteristics of the LED chip.

On the other hands, in order to increase a contact area between air, a plurality of grooves are formed on a bottom surface of the base substrate 110 or the present invention has a structure obtained by unifying the base substrate 110 and a heat sink (not shown).

And, in order to prevent the bending phenomenon during the mounting of the LED chip, it is preferable that the thickness of the base substrate 110 is ranging from 800 nm to 1,000 nm.

The insulating layer 120 is formed in the surface of a remaining base substrate 110 except a chip mounting region A in the base substrate 110.

Herein, as the chip mounting region A is a region where the high reflection layer 150 exposed to outside through a cavity 131 exists, according to a structure of the high reflection layer 150, a width of the high reflection layer 150 is equal to or larger than that of the chip mounting region A.

And, according to the manufacturing method of the present invention described hereinafter, the chip mounting region A may be fabricated in various shapes. As FIG. 2 is a plan view showing a substrate of an LED module in accordance with an embodiment of the present invention, for example, the chip mounting region A may be fabricated in a shape of a circle as shown in FIG. 2, and it may be fabricated in an arbitrary shape such as a rectangle, an ellipse, a polygon or the like.

Referring back to FIG. 1, the insulation layer 120 has a structure that a glass fiber is dented into a thermosetting resin. Since such insulating layer 120 is manufactured in a shape of a sheet, it can be stacked on the base substrate 110. An epoxy resin, a phenol resin, a silicon resin, an acrylic resin or the like can be used as the thermosetting resin.

On the other hands, in order to effectively discharge heat generated in the LED chip 160, an inorganic filler having excellent thermal conductivity may be included into the insulation layer 120. The inorganic filler may be made of heterogeneous particles that the average grain diameters thereof are different from each other. For example, it may be made of particles having the average grain diameter ranging from 0.6 μm to 2.4 μm and particles having the average grain diameter ranging from 5 μm to 20 μm.

Like this, by mixing coarse particles having large average grain diameters and fine particles having small average grain diameters, since a dense filling is allowed in comparison with a case that each is independently used, the present invention can obtain the more excellent thermal conductivity.

The electrode layer 130 performs an electrical signal transmission with the LED chip 160 by being formed in a predetermined pattern on the insulation layer 120. Accordingly, the electrode layer 130 can include at least one or two material having excellent thermal conductivity selected from a group consisting of nickel, copper, gold, silver, tin and cobalt.

Reviewing the structure of the electrode layer 130 in more detail, the electrode layer 130 may be made of a bottom seed layer and a top metal layer. The seed layer is a thin metal layer formed on a surface of the insulating layer 120 by using a sputtering process and the metal layer is formed through an electrolyte plating process by using the seed layer as a drawing line.

Further, the metal layer can be formed by using various plating processes well known to those skilled in the art, e.g., an additive process, a subtractive process, a semi-additive process or the like, and the seed layer may be omitted according to the plating process.

On the other hands, the plating layer may be further formed on a surface of the electrode layer 130 so as to allow the LED chip 160 be wire bonded or soldered. Gold Au is used for forming the plating layer which can be formed by using electroless plating processes such as an electoless nickel immersion gold (ENIG), an electroless nickel autocatalytic gold (ENAG), an electroless nickel electroless palladium immersion gold (ENEPIG) or the like.

The high reflection layer 150 is a metal thin film having a thickness ranging from 2 μm to 3 μm formed uniformly on the chip mounting region A of the base substrate 110. In the embodiments of the present invention, although the high reflection layer 150 is made of aluminum Al and formed by a sputtering process, it can be made of a metal material capable of being formed by using the sputtering process, that is, titanium Ti, silver Ag, nickel Ni, chrome Cr or the like. The common characteristics of such materials have high light reflectivity except a point that it can be formed by using the sputtering process.

Like this, as the substrate for the LED module in accordance with the present invention takes a structure that the LED chip 160 is mounted on the high reflection layer 150 having a high light reflectivity, it can implement an effective illumination by reflecting the light emitted from the LED chip 160 by the high reflection layer 150.

And also, since the high reflection layer 150 is formed only on the chip mounting region A where the light of the LED chip 160 reaches directly, the manufacturing cost thereof can be reduced by not forming the high reflection layer 150 for the unnecessary region.

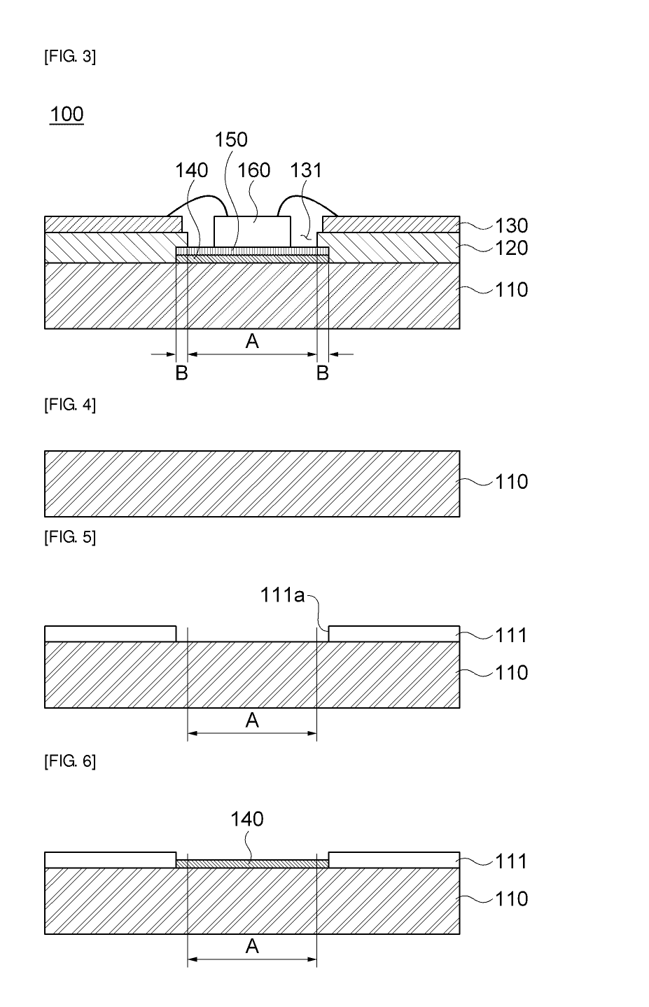

On the other hands, in FIG. 1, although the substrate for the LED module of a structure that a width of the high reflection layer 150 is equal to that of the chip mounting region A, the substrate for the LED module in accordance with another embodiment, as shown in FIG. 3, may has a structure that the width of the high reflection layer 150 is larger than that of the chip mounting region A. accordingly, the high reflection layer 150 is formed to the chip mounting region A in the base substrate 110 as well as a region B extended from the chip mounting region A, and the insulation layer 120 covers the high reflection layer 150 of the region B.

Like this, in the another embodiment of the present invention, the high reflection layer 150 and the insulation layer 120 are joined by an area corresponding to the region B, the bondability between the high reflection layer 150 and the base substrate 110 can be drastically increased, thereby improving a reliability of products.

And also, the heat generated in the LED chip 160 is discharged through the bottom surface of the high reflection layer 150 as well as the junction surface between the high reflection layer 150 and the insulation layer 120, thereby performing an effective discharge.

Herein, it is preferable that the width of the region B is ranging from 0.01 to 0.2 of the width of the chip mounting region A. Although above-described effects can be further exhibited as being the width of the region B longer, on the contrary, the process cost for forming the high reflection layer 150 may increase. Accordingly, it is preferable that the width of the region B has an appropriate value within the above-described range.

In case when the base substrate 110 is made of metal material, the oxide layer 140 may be formed between the high reflection layer 150 and the base substrate 110 in order to electrically insulate the base substrate 110 and the high reflection layer 150 and to reduce the light absorption rate of the substrate.

The oxide layer 140 can be formed by anodizing or electrolyte oxidizing the surface of the base substrate 110 of a metal material. For example, if the base substrate 110 is made of aluminum Al, the oxide layer 140 may be made of anodic oxidation alumina Al₂O₃. Since the alumina Al₂O₃ has excellent insulation property and reflectivity, although the thickness of the oxide layer 140 is thin, the insulation between the base substrate 110 and the high reflection layer 150 can be sufficiently secured and the light amount from the LED chip 160 can be increased by reducing the light absorption rate of the base substrate 110.

The LED chip 160 mounted on the top surface of the high reflection layer 150 can be formed as a structure including an n-type semiconductor layer, a p-type semiconductor layer and an active layer sandwiched therebetween, wherein it has a structure that the light is discharged by coupling the electrons with holes in the active layer. Merely, the present invention can be applied to various types of LED chips independently of whether the structure of the LED chip is a vertical type, a horizontal type or a flip-chip type, and it is not limited to a specific type of LED chips.

The mounting of such LED chip 160 may utilize a joining method such as a chip bonder, a soldering, a spot welding, a heat discharging pad or a heat discharging tape, a heat discharging paste, or the like.

And, although the coupling between the LED chip 160 and the electrode layer 30 can be connected as various structures according to the shapes and characteristics of the components, in general, it can use a wire bonding. It is preferable that the wire bonding is a gold Au wire bonding; and, the LED chip 160 and the electrode layer 130 are electrically connected through the wire bonding.

Herein, a method for manufacturing a substrate for an LED module in accordance with the embodiments of the present invention will be reviewed.

FIGS. 4 to 9 are process diagrams showing a method for manufacturing a substrate of an LED in accordance with another embodiment of the present invention.

The method for manufacturing the substrate for the LED module in accordance with the embodiments of the present invention prepares a base substrate 110 at first, as shown in FIG. 4.

The base substrate 110 may be a substrate made of a metal material including at least one metal selected from a group consisting of aluminum Al, magnesium Mg, manganese Mn, zinc Zn, titanium Ti, hafnium Hf, tantalum Ta and niobium Nb or an alloy thereof.

Thereafter, as shown in FIG. 5, a mask 111 formed thereon an opening unit 111a according to a predetermined pattern is attached to a surface of the base substrate 110.

Since a high reflection layer 150 mounted thereon the LED chip 160 is formed on a surface of the base substrate 110 which is exposed to an outside thereof through the opening unit 111a, it is preferable that the opening unit 111a is formed considering the mounting position of the LED chip 160.

At this time, the opening unit 111a may has an arbitrary shape such as a circle, a rectangle, an ellipse, a polygon or the like; and, accordingly, the surface of the base substrate 110 exposed through the opening unit 111a also has the arbitrary shape such as the circle, the rectangle, the ellipse, the polygon or the like according to the shape of the opening unit 111a.

A width of the opening unit 111a may be equal to or larger than that of the chip mounting region A. In FIG. 5, there is previously disclosed as an example that the width of the opening unit 111a is larger than that of the chip mounting region A.

In case when the width of the opening unit 111a is larger than that of the chip mounting region A, since the width of the high reflection layer 150 formed by the following processes becomes larger than that of the chip mounting region A, the structure of the substrate for the LED module as shown in FIG. 3 can be manufactured.

At this time, it is preferable that a difference between the width of the opening unit 111a and the width of the chip mounting region A is ranging from 0.01 to 0.2 of the width of the chip mounting region A.

Thereafter, as shown in FIG. 6, an oxide layer 140 is formed by oxidizing the surface of the base substrate 110 exposed through the opening unit 111a.

The oxidation process may be an anodizing process or a plasma electrolyte oxidation process.

Reviewing an oxidation process using the anodizing process in detail, for example, in case when the base substrate 110 is aluminum Al, the surface of the base substrate 110 exposed through the opening unit 111a is reacted with an electrolyte solution, thereby forming aluminum ions Al³⁺ on an interface surface therebetween. At this time, if the current density is concentrated by the voltage applied to the base substrate 110, the further aluminum ions Al³⁺ are formed, in this results, a plurality grooves are formed on the surface of the base substrate 110 exposed through the opening unit 111a. And then, the oxygen ions O²⁻ are moved toward the grooves due to the force of electric field and are reacted with the aluminum ions Al³⁺; and, accordingly, the oxide layer 140 made of alumina Al₂O₃ is formed on the surface of the base substrate 110 exposed through the opening unit 111a.

After the oxidation process, according to the case, the surface of the oxide layer 140 can be polished by additionally proceeding to a step of polishing the whole surface of the base substrate 110. Generally, since the reflectivity of the lights are increased as the wavelength of lights to be incident is longer and the incidence surface is more flat, the amount of lights from the LED chip 160 can be increased by proceeding to such polishing process.

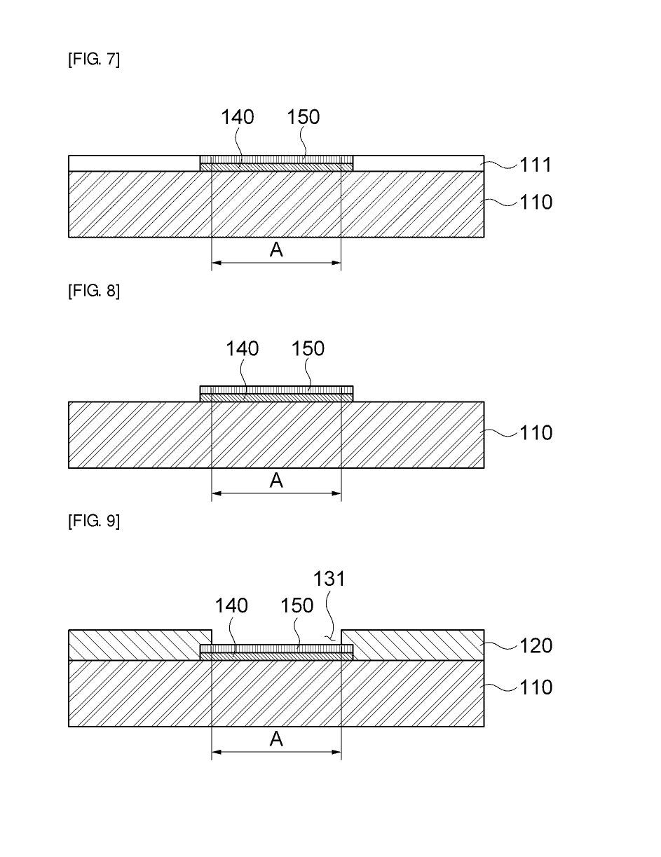

Thereafter, as shown in FIG. 7, the high reflection layer 150 is formed on the oxide layer 140.

If the surface of the base substrate 110 is deposited under a condition that the mask 111 is attached, the high reflection layer 150 is deposited on the surface of the oxide layer 140 exposed through the opening unit 111a.

At then, if the mask 111 is removed, as shown in FIG. 8, the base substrate 110 provided with the oxide layer 140 and the high reflection layer 150 formed on the top surface of the oxide layer 140.

Herein, the deposition process may be a conventional sputtering process. As the sputtering process is a technology to form a thin film by depositing metal particles on a surface of a substrate, although the sputtering process is implemented by using aluminum Al in the embodiments of the present invention, it can be implemented by using metal materials, e.g., nickel, chrome, silver or the like, capable of performing the sputtering process.

In addition, the deposition process may be the metal layer can be also formed by using conventional deposition processes, well known to those skilled in the art, such as a plating process, a thermal deposition process, an e-beam deposition process, a physical vapor deposition process, a chemical vapor deposition process.

And then, as shown FIG. 9, the insulation layer 120 is stacked on the surface of the base substrate 110 except the high reflection layer 150.

Particularly, the insulation layer 120 may be a copper clad laminate (CCL) that a copper layer is thermo-compressed in vacuum on one surface of the insulation sheet of a structure where a glass fiber is dented in the thermosetting resin such as epoxy. Such copper clad laminate CCL are stacked on the base substrate 110 under a condition that the surfaces of the copper layers are facing upwards.

At this time, the insulation layer 120 previously formed thereon a cavity can be stacked, as another method, a coverlay is tack welded on the chip mounting region A, after the insulation layer 120 is stacked on the whole surface of the base substrate 110, the cavity can be fabricated by removing the coverlay.

Herein, the insulation layer 120 stacked on the base substrate 110 covers a remaining area except the chip mounting region A in the base substrate 110. Accordingly, if the mask 111 that the width of the opening unit 111a is larger than that of the chip mounting region A is attached in the foregoing processes, the width of the high reflection layer 150 formed according to the following processes becomes larger than that of the chip mounting region A, in this results, a portion of the insulation layer 120 covers the high reflection layer 150 exceeding the chip mounting region A, as shown in FIG. 9.

If the insulation layer 120 is stacked, finally, the substrate for the LED module in accordance with the embodiments of the present invention is finished by forming the electrode layer 130 on the insulation layer 120.

The electrode layer 130 can be formed by using a process well known to those skilled in the art such as an additive process, a subtractive process, a semi-additive process or the like using a copper film formed on one surface of the insulation layer 120.

Like this, according to the method for manufacturing the substrate for the LED module in accordance with the embodiments of the present invention, the oxide layer 140 as a light reflection member and the high reflection layer 150 on the oxide layer 140 can be formed with a easy and simple method through the masking process. In these results, the simplification of the processes can be implemented and the process cost can be drastically reduced.

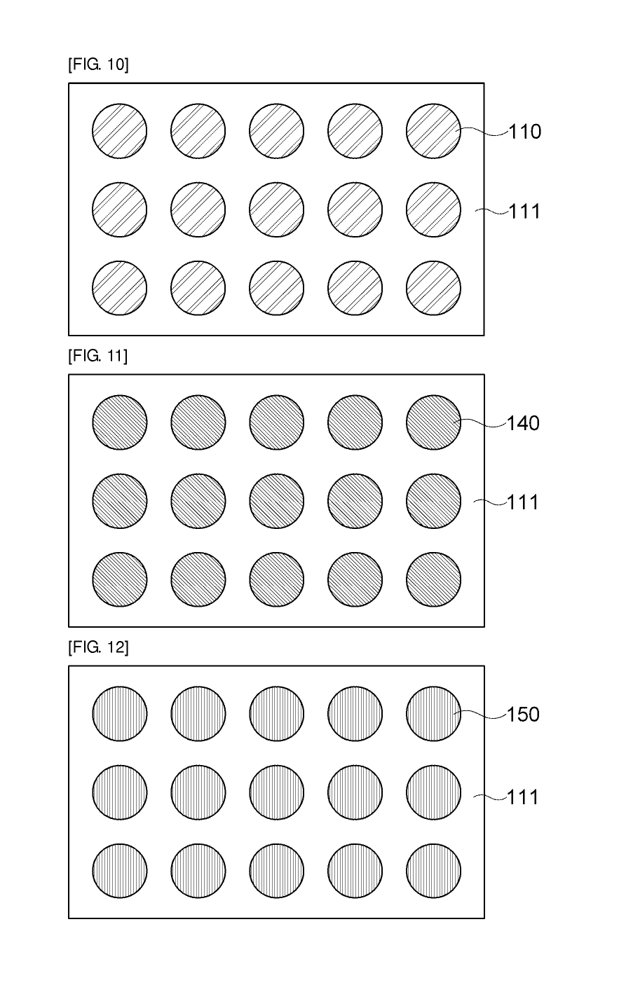

And, the manufacturing method through such masking process has an advantage of applying to a mass production of products. As FIGS. 10 to 12 are partial process diagrams showing a method for manufacturing a substrate of an LED in accordance with another embodiment of the present invention, as shown in FIG. 10, under a condition that the mask formed thereon a plurality of opening unit is attached to the base substrate, as shown in FIG. 11, the whole surface of the base substrate is oxidized, as shown in FIG. 12, and a plurality of high reflection layers are formed with proceeding to the metal deposition process. That is, a plurality of products can be manufactured by attaching the mask formed thereon a plurality of opening units and by preceding each process once.

And, according to the method for manufacturing the substrate for the LED module in accordance with the embodiments of the present invention, since the sizes and shapes of the opening unit 111a are arbitrarily set and the sizes and shapes of the high reflection layer 150 corresponding thereto can be formed, the present invention is not limited to the space for mounting the LED chip and can implement the LED chip mounting space of various sizes and shapes.

According to the method for manufacturing the LED module in accordance with the embodiment of the present invention, it can drastically realize the simplification of processes and reduce the manufacturing cost by forming the oxide layer as a light reflection member with a simple and easy method by using a masking process and the high reflection layer provided on the oxide layer.

And, since the high reflection layer can be formed in various sizes and shapes according to the size and distribution of the LED chips, the present invention does not limit to the space for mounting the LED chips and can control the optical property of the LED chips by allowing the LED chips to be distributed effectively.

Embodiments of the invention have been discussed above with reference to the accompanying drawings. However, those skilled in the art will readily appreciate that the detailed description given herein with respect to these figures is for explanatory purposes as the invention extends beyond these limited embodiments. For example, it should be appreciated that those skilled in the art will, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are numerous modifications and variations of the invention that are too numerous to be listed but that all fit within the scope of the invention.

1. A substrate for an LED module, comprising:
a base substrate;
an insulating layer formed on a remaining region except a chip mounting region A in the base substrate;
an electrode layer formed on the insulating layer;
an oxide layer formed on the chip mounting region A of the base substrate; and
a high reflection layer formed on a top surface of the oxide layer.

2. The substrate for an LED module according to claim 1, wherein each of the oxide layer is made of oxide formed by oxidizing the base substrate.

3. The substrate for an LED module according to claim 2, wherein the oxide layer includes any one or two among alumina Al₂O₃, magnesium oxide MgO, manganese oxide MnO, zinc oxide ZnO, titanium TiO₂, hafnium oxide HfO₂, tantalum oxide Ta₂O₅ and niobium Nb₂O₃.

4. The substrate for an LED module according to claim 1, wherein the chip mounting region A of the base substrate is in a shape of circle or in a shape of rectangle.

5. The substrate for an LED module according to claim 1, wherein the high reflection layer is a metal thin film formed by a deposition process.

6. The substrate for an LED module according to claim 5, wherein the high reflection layer includes any one among aluminum Al, titanium Ti, silver Ag, nickel Ni and chrome Cr or an alloy thereof.

7. The substrate for an LED module according to claim 1, wherein the base substrate is made of any one among aluminum Al, magnesium Mg, manganese Mn, zinc Zn, hafnium Hf, tantalum Ta and niobium Nb or an alloy thereof.

8. The substrate for an LED module according to claim 1, further comprising:
an LED chip mounted on the top surface of the reflection layer and connected to the electrode layer by a wire bonding.

9. The substrate for an LED module according to claim 1, further comprising:
a plating layer formed on a surface of the electrode layer so as to be wire bonded to the LED chip.

10. A substrate for an LED module, comprising:
a base substrate;
an oxide layer on a chip mounting region A and a region B connected from the chip mounting region A in the base substrate;
a high reflection layer formed on the oxide layer
an insulating layer formed on a remaining region except a chip mounting region A in the base substrate, wherein the insulating layer covers the oxide layer and the high reflection layer of the region B extended from the chip mounting region A; and
an electrode layer formed on the insulating layer.

11. The substrate for an LED module according to claim 10, wherein a width of the region B extended from the chip mounting region A and a width of the chip mounting region A are ranging from 0.01 to 0.2.

12. A method for manufacturing a substrate for an LED module, comprising:
preparing a base substrate;
attaching a mask formed thereon an opening unit according to a predetermined pattern on a surface of the base substrate;
oxidizing the surface of the base substrate exposed through the opening unit;
forming a an-high reflection layer on an oxide layer formed by an oxidation process;
after removing the mask, forming an insulating layer on a remaining region except a chip mounting region A in the base substrate; and
forming an electrode layer on the insulating layer.

13. The method for manufacturing a substrate for an LED module according to claim 12, wherein the forming a high reflection layer is performed by metal deposition processing the surface of the base substrate under the condition that the mask is attached.

14. The method for manufacturing a substrate for an LED module according to claim 13, wherein the metal deposition process utilizes any one among a sputtering, a plating, a thermal deposition, an e-beam deposition, a physical vapor deposition (PVD) and a chemical vapor deposition (CVD).

15. The method for manufacturing a substrate for an LED module according to claim 12, wherein the opening unit has a shape of circle or rectangle.

16. The method for manufacturing a substrate for an LED module according to claim 12, wherein a width of the opening unit is larger than that of the chip mounting region A in the base substrate.

17. The method for manufacturing a substrate for an LED module according to claim 16, wherein a difference between the width of the opening unit and the width of the chip mounting region A is ranging from 0.01 to 0.2 of the chip mounting region A.

18. The method for manufacturing a substrate for an LED module according to claim 12, wherein the oxidation treatment is an anodizing process or a plasma electrolytic oxidation process.

19. The method for manufacturing a substrate for an LED module according to claim 12, further comprising,
after the oxidizing,
polishing a whole surface of the base substrate.

20. The method for manufacturing a substrate for an LED module according to claim 12, wherein the electrode layer is formed by any one among an additive process, a subtractive process or a semi-additive process.

21. The method for manufacturing a substrate for an LED module according to claim 12, wherein, in the forming an insulating layer, the insulting layer is formed so as to cover the oxide layer and the high refection layer exceeding to the chip mounting region A of the base substrate.

22. The method for manufacturing a substrate for an LED module according to claim 12, further comprising:
after the forming an electrode layer,
forming a plating layer on a surface of the electrode layer through an electroless plating such as an electoless nickel immersion gold (ENIG), an electroless nickel autocatalytic gold (ENAG), an electroless nickel electroless palladium immersion gold (ENEPIG) or the like.
